(19) United States
(12) Patent Application Publication
(10) Pub. No.: US 2026/0173873 A1
(43) Pub. Date: Jun. 18, 2026

(54) BONDING TO ENHANCE THERMAL DISSIPATION FOR BACKSIDE POWER DISTRIBUTION NETWORK

(71) Applicant: International Business Machines Corporation, Armonk, NY (US)

(72) Inventors: Sarabjot Singh, Albany, NY (US); Ruilong Xie, Niskayuna, NY (US); Nicolas Jean Loubet, GUILDERLAND, NY (US); Joshua Mark Rubin, Albany, NY (US)

(21) Appl. No.: 18/981,466

(22) Filed: Dec. 14, 2024

(51) Int. Cl. H01L 23/373; H01L 21/02

(52) U.S. Cl. CPC H10W 40/253; H10P 14/2903; H10P 14/2905; H10P 14/2908; H10P 14/2921; H10P 14/40; H10P 14/6322; H10P 14/6326

(57) ABSTRACT

Bonding techniques for thermal management in semiconductor devices having a backside power distribution network are provided. In one aspect, a semiconductor device includes: a first wafer; and a second wafer attached to the first wafer, where the first wafer has a first component of an interface between the first wafer and the second wafer, and the second wafer has a second component of the interface between the first wafer and the second wafer, and where at least one of the first component and the second component of the interface between the first wafer and the second wafer includes dual crystalline and amorphous materials. The first wafer can include a heat source such as a backside power distribution network. A method of fabricating the present semiconductor devices is also provided.

### BACKGROUND

The present invention relates generally to the electrical, electronic and computer arts and, more particularly, to bonding techniques for thermal management in semiconductor devices having a backside power distribution network.

With traditional semiconductor device architectures, both signal and power networks are often located on the frontside of a semiconductor wafer. However, with more complex circuit designs, space on the frontside of the semiconductor wafer is at a premium. As such, backside power distribution networks have been implemented.

As its name implies, a backside power distribution network provides power interconnections on the backside of a wafer. Relocating the power interconnections from the frontside to the backside of the wafer advances scaling capabilities, as well as overall device efficiency and power density. However, with a greater power density comes the increased challenge of effective heat dissipation.

### BRIEF SUMMARY

Principles of the invention provide bonding techniques for thermal management in semiconductor devices having a backside power distribution network. In one aspect, a semiconductor device is provided. The semiconductor device includes: a first wafer; and a second wafer attached to the first wafer, where the first wafer has a first component of an interface between the first wafer and the second wafer, and the second wafer has a second component of the interface between the first wafer and the second wafer, and where at least one of the first component and the second component of the interface between the first wafer and the second wafer includes dual crystalline and amorphous materials.

In another aspect, another semiconductor device is provided. The semiconductor device includes: a first crystalline material disposed on a first wafer, where the first wafer includes a heat source (e.g., a backside power distribution network); a first amorphous material disposed on the first crystalline material; a second amorphous material disposed on the first amorphous material; a second crystalline material disposed on the second amorphous material; and a second wafer disposed on the second crystalline material.

In yet another aspect, a method of forming a semiconductor device is provided. The method includes: depositing a first crystalline material on a first wafer; depositing a first amorphous material on the first crystalline material; depositing a second crystalline material on a second wafer; depositing a second amorphous material on the second crystalline material; and bonding the first wafer and the second wafer to one another via fusion bonding between the first amorphous material and the second amorphous material.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a diagram of an exemplary methodology for dual crystalline and amorphous bonding according to one or more embodiments of the present invention; and

FIGS. 2-10 are cross-sectional diagrams of an exemplary methodology for formation of a semiconductor device having a backside power distribution network which employs the present dual crystalline and amorphous bonding techniques according to one or more embodiments of the present invention;

FIG. 11 is a cross-sectional diagram of an exemplary variant of the present semiconductor device having a crystalline material on only one side of the bonding interface according to one or more embodiments of the present invention; and

FIG. 12 is a cross-sectional diagram of another exemplary variant of the present semiconductor device having a crystalline material on only another side of the bonding interface according to one or more embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor device (e.g., semiconductor device 10010) is provided. The semiconductor device includes: a first wafer (e.g., device wafer 2004); and a second wafer (e.g., carrier wafer 5004) attached to the first wafer, where the first wafer has a first component of an interface between the first wafer and the second wafer, and the second wafer has a second component of the interface between the first wafer and the second wafer, and where at least one of the first component and the second component of the interface between the first wafer and the second wafer includes dual crystalline and amorphous materials (e.g., first crystalline material 3004/second crystalline material 5006 and first amorphous material 4004/second amorphous material 6004, respectively).

In another aspect, another semiconductor device (e.g., semiconductor device 10010) is provided. The semiconductor device includes: a first crystalline material (e.g., first crystalline material 3004) disposed on a first wafer (e.g., device wafer 2004), where the first wafer includes a heat source (e.g., backside power distribution network 10004); a first amorphous material (e.g., first amorphous material 4004) disposed on the first crystalline material; a second amorphous material (e.g., second amorphous material 6004) disposed on the first amorphous material; a second crystalline material (e.g., second crystalline material 5006) disposed on the second amorphous material; and a second wafer (e.g., carrier wafer 5004) disposed on the second crystalline material.

In yet another aspect, a method of forming a semiconductor device is provided. The method includes: depositing a first crystalline material (e.g., first crystalline material 3004) on a first wafer (e.g., device wafer 2004); depositing a first amorphous material (e.g., first amorphous material 4004) on the first crystalline material; depositing a second crystalline material (e.g., second crystalline material 5006) on a second wafer (e.g., carrier wafer 5004); depositing a second amorphous material (e.g., second amorphous material 6004) on the second crystalline material; and bonding the first wafer and the second wafer to one another via fusion bonding between the first amorphous material and the second amorphous material.

Techniques as disclosed herein can provide substantial beneficial technical effects. Some embodiments may not have these potential advantages and these potential advantages are not necessarily required of all embodiments. By way of example only and without limitation, one or more embodiments of the present semiconductor devices can provide one or more of:
Implementation of dual crystalline and amorphous bonding materials for attachment to a carrier wafer in order to maximize both thermal conductivity and bonding strength for semiconductor devices having a backside power distribution network;
Whereby the crystalline bonding material exhibits higher thermal conductivity than traditional bonding layers; and
Whereby the amorphous bonding material has greater bonding strength than the crystalline bonding material and thus enhances attachment to the carrier wafer.

As highlighted above, thermal management is an important consideration with semiconductor devices having a backside power distribution network, which can increase power density. Namely, as power density increases, heat density becomes a major concern. Thus, being able to increase the thermal conductivity at the device wafer-carrier wafer bonding interface is advantageous. Alternative bonding materials, such as aluminum nitride (AlN), exhibit an increased thermal conductivity, as compared to traditional bonding materials. However, without taking bonding strength into consideration, implementation of these materials can cause voiding issues at the bonding interface.

Advantageously, it has been found herein that a bonding interface having dual bonding materials can be implemented in order to get the best of both worlds in terms of thermal conductivity and bonding strength. Namely, a crystalline bonding material such as crystalline AlN is used to achieve a greater thermal conductivity over traditional bonding materials and makes up a bulk of the bonding interface. While better in terms of thermal conductivity, this crystalline form of the bonding material can, however, lower bonding strength and cause voiding issues at the bonding interface. Thus, a thinner, amorphous bonding material such as amorphous AlN is used in conjunction with the crystalline bonding material to achieve a greater bonding strength.

The term “thermal conductivity” as used herein refers generally to how easily heat is transmitted through a given material. For illustrative purposes only, in the examples presented below, a source of the heat (i.e., heat source) is a backside power distribution network. However, it is to be understood that the present techniques are more generally applicable to any scenario where it is beneficial to maximize both thermal conductivity and bonding strength.

Reference will be made throughout the description to crystalline and amorphous forms of the present bonding materials. Crystalline materials often exhibit higher thermal conductivity than their amorphous counterparts. In general, this higher thermal conductivity is due to the long-range order in crystals which permits the propagation of vibrational modes and limits the phonon-phonon scattering present in amorphous (non-crystalline) materials having a disordered structure. The long-range order of crystalline materials can, however, reduce bonding strength and undesirably result in voiding issues at the bonding interface. Amorphous materials, on the other hand, have a greater bonding strength than their crystalline counterparts. The present techniques leverage these beneficial qualities of both (crystalline and amorphous) materials.

Further, the term ‘crystalline’ as used herein is intended to refer generally to any crystalized form of the present bonding materials, whether it be a monocrystalline or polycrystalline solid. As would be apparent to one having ordinary skill in the art and, as its name implies, a monocrystalline solid has a single crystal lattice orientation with a uniform structure throughout. By contrast, a polycrystalline solid contains multiple crystals with their corresponding lattice orientations. Any of the crystalline materials described herein can be monocrystalline or polycrystalline solids. Further in that regard, when embodiments are presented herein that include multiple (e.g., first and second) crystalline materials, these materials may both be monocrystalline or polycrystalline solids or, alternatively, one a monocrystalline solid and the other a polycrystalline solid.

An overview of the present techniques is now provided by way of reference to methodology 1000 of FIG. 1 for dual crystalline and amorphous bonding. The process begins with the formation of a first component of a bonding interface (or simply interface) on a device wafer and a complementary second component of the bonding interface on a carrier wafer. The terms ‘first’ and ‘second’ may also be used herein when referring to the device wafer and the carrier wafer, respectively. As will be described in detail below, the first component and the second component of the bonding interface between the (first) device wafer and the (second) carrier wafer will each include the present dual crystalline and amorphous materials.

Namely, in no particular order, in step 1002 a first crystalline material is deposited onto the device wafer. As will be described in detail below, embodiments are contemplated herein where the present techniques are implemented during the formation of a semiconductor device having a backside power distribution network, and dual crystalline and amorphous materials are employed to maximize both bonding strength and heat dissipation. In that case, the device wafer includes a device layer disposed on a substrate, and a back-end-of-line layer (also referred to herein as a ‘frontside interconnect layer’—see below) disposed on the device layer, whereby the first crystalline material is deposited onto the back-end-of-line layer. However, as highlighted above, the present techniques are more generally applicable to any scenario where it is beneficial to maximize both thermal conductivity and bonding strength through the use of crystalline and amorphous materials.

As highlighted above, the first crystalline material is implemented to maximize heat dissipation due to its higher thermal conductivity. Thus, according to an exemplary embodiment, the first crystalline material makes up a bulk of the first component of the bonding interface between the device wafer and the carrier wafer.

As highlighted above, use of a crystalline material can undesirably lead to voids at the bonding interface. Thus, in step 1004 a first amorphous material is deposited onto the first crystalline material. The first amorphous material is implemented to maximize bonding strength. The first crystalline material and the first amorphous material together form the first component of the bonding interface on the device wafer.

A similar process is performed on the counterpart carrier wafer. Namely, in step 1006 a second crystalline material is deposited onto the carrier wafer. According to an exemplary embodiment, the second crystalline material makes up a bulk of the second component of the bonding interface between the device wafer and the carrier wafer.

As highlighted above, use of a crystalline material can undesirably lead to voids at the bonding interface. Thus, in step 1008 a second amorphous material is deposited onto the second crystalline material. The second amorphous material is implemented to maximize bonding strength. The second crystalline material and the second amorphous material together form the second component of the bonding interface on the carrier wafer.

Suitable first and second crystalline materials include, but are not limited to, crystalline solids of dielectric materials such as AlN, titanium oxide (TiO₂), silicon dioxide (SiO₂), diamond, boron nitride (BN) and/or beryllium oxide (BeO), which can be deposited using techniques known to those of skill in the art. For instance, by way of example only, depositing AlN using a process such as physical vapor deposition (PVD) results in the formation of a crystalline film of the material. Crystalline AlN has improved heat dissipation when compared to SiO₂ (i.e., about 23 percent higher). However, crystalline AlN has been found to leave triple junction voids at the grain boundaries, thereby decreasing its bonding strength. This is why amorphous materials are also employed at the bonding interface to increase bond strength.

For the formation of crystalline materials that may exceed the thermal budget, such as diamond or BN, a standard transfer process may be employed to deposit the first and/or second crystalline materials whereby the crystalline material is first formed/grown on a donor substrate (not shown in the figures), and then transferred/bonded to the corresponding device wafer or carrier wafer, as specified above, either directly or via bonding films (not shown in the figures) on one or two sides of the bonding interface (e.g., SiO₂, Si₃N₄, etc.). After which, the donor substrate can be removed using known techniques. Given the instant description, it would be readily apparent those of skill in the art how to implement such a layer transfer process in accordance with the present techniques.

Suitable first and second amorphous materials include, but are not limited to, amorphous solids of dielectric materials such as AlN, TiO₂, SiO₂ and/or silicon carbon nitride (SiCN), which can be deposited using techniques known to those of skill in the art. For instance, by way of example only, depositing AlN using a process such as chemical vapor deposition (CVD) results in the formation of an amorphous film of the material that is conformal, offering better coverage and adhesion.

Thus, the present techniques generally involve the combination of (first) crystalline and amorphous materials on the device wafer formed from any crystalline and amorphous dielectric materials, respectively, and counterpart (second) crystalline and amorphous materials on the carrier wafer also formed from any crystalline and amorphous dielectric materials, respectively. For instance, any combination of the dielectric materials provided above can be employed. Namely, embodiments are contemplated herein where crystalline and amorphous counterparts of the same dielectric material or, alternatively, crystalline and amorphous forms of different dielectric materials are employed for the first crystalline material vis-à-vis the first amorphous material, and/or for the second crystalline material vis-à-vis the second amorphous material, and/or for the first crystalline and amorphous materials vis-à-vis the second crystalline and amorphous materials.

In step 1010, the device wafer and the carrier wafer are bonded to one another via fusion bonding between the first amorphous material (of the device wafer) and the second amorphous material (of the carrier wafer). By way of example only, this fusion bonding between the first and second amorphous materials can involve thermal compression bonding, hybrid bonding, etc. Attachment to the carrier wafer enables further processing of the device wafer to be performed. For instance, by way of example only, processing can be employed on the device wafer to form additional backside structures on the device wafer such as a backside power distribution network. As highlighted above, implementation of a backside power distribution network can provide increased power density. In that regard, the enhanced heat dissipation provided by the present dual crystalline and amorphous bonding techniques advantageously compensates for the resulting heat density increase.

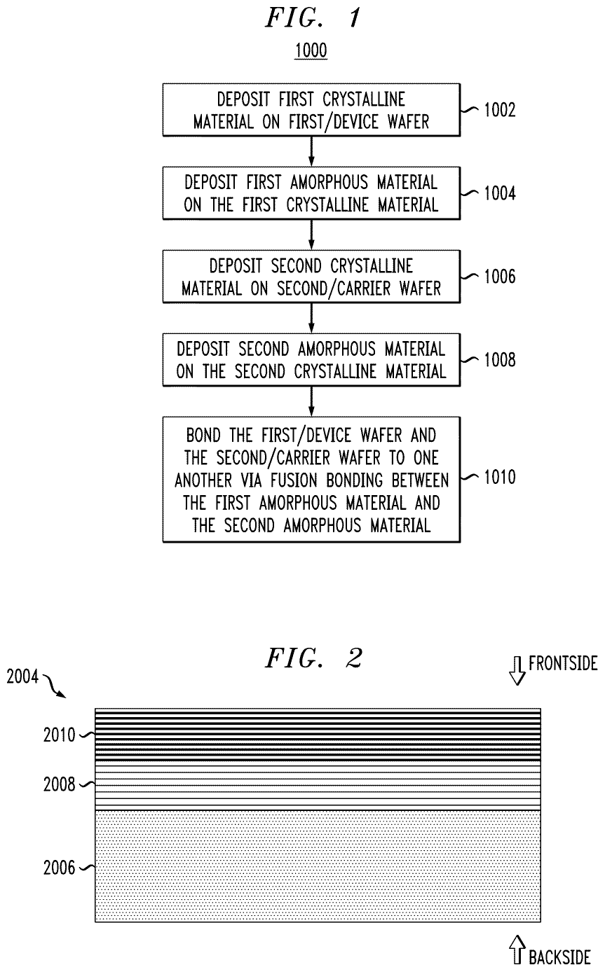

Given the above overview, an exemplary implementation of the present dual crystalline and amorphous bonding techniques in the formation of a semiconductor device 10010 having a backside power distribution network 10004 will now be described by way of reference to FIGS. 2-10, which are all cross-sectional views. Referring to FIG. 2, the process begins with a device wafer 2004 having a substrate 2006, a device layer 2008 disposed on the substrate 2006, and a back-end-of-line layer 2010 disposed on the device layer 2008.

According to an exemplary embodiment, the substrate 2006 is a bulk semiconductor wafer, such as a bulk silicon (Si), bulk germanium (Ge), bulk silicon germanium (SiGe) and/or bulk III-V semiconductor wafer. Alternatively, the substrate 2006 can be a semiconductor-on-insulator (SOI) wafer. A SOI wafer includes an SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, the substrate 2006 may already have pre-built structures (not shown) such as transistors, diodes, capacitors, resistors, interconnects, wiring, etc.

The device layer 2008 generally includes components commonly found in semiconductor devices such as logic circuits having transistors, capacitors, resistors and/or diodes. While the individual components present in the device layer 2008 are not specifically shown in the figures, one skilled in the art would understand how such a device layer 2008 is implemented for a given semiconductor device application. According to an exemplary embodiment, the device layer 2008 includes planar and/or non-planar transistors, with the latter including, e.g., fin-field effect transistors (FinFETs), nanowire-or nanosheet-FETs, vertical FETs, etc.

The back-end-of-line layer 2010 generally includes structures commonly formed in the back end of line during semiconductor device fabrication. Namely, in the back end of line, individual devices such as the above-referenced transistors in the device layer 2008 get interconnected through a series of metal layers interspersed with dielectric material. Thus, the back-end-of-line layer 2010 may also be referred to herein as a ‘frontside interconnect layer,’ since it is present on the frontside of the device wafer 2004 (see FIG. 2). For instance, conductive structures like vias and metal lines can be employed to connect a device to one or more other devices, to external connections, and the like, with the metal lines making lateral connections and the vias making vertical connections amongst different metallization levels. Standard metallization techniques can be employed to form the back-end-of-line layer 2010. While the individual interconnects present in back-end-of-line layer 2010 are not specifically shown in the figures, one skilled in the art would understand how such a back-end-of-line layer 2010 is implemented for a given semiconductor device application.

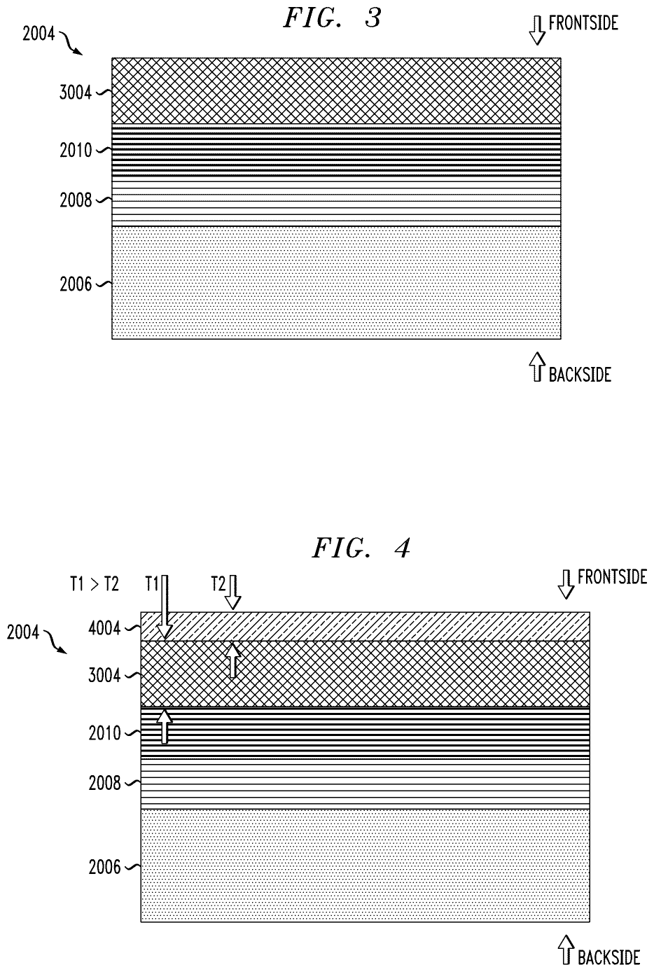

Next, the first component of the bonding interface (or simply interface) is formed on the device wafer 2004. A highlighted above, this first component of bonding interface includes dual crystalline (FIG. 3) and amorphous (FIG. 4) materials. Namely, referring to FIG. 3, a first crystalline material 3004 is deposited onto the device wafer 2004. Specifically, the first crystalline material 3004 is deposited directly on the back-end-of-line layer 2010. Referring to FIG. 4, a first amorphous material 4004 is deposited on the first crystalline material 3004. The first crystalline material 3004 and the first amorphous material 4004 together form the first component of the bonding interface on the device wafer 2004.

As described in detail above, the present dual crystalline and amorphous bonding interface maximizes both thermal conductivity and bonding strength. Namely, crystalline materials often exhibit higher thermal conductivity than their amorphous counterparts. The use of crystalline materials at the bonding interface can, however, reduce bonding strength and undesirably result in voiding issues at the bonding interface. Amorphous materials, on the other hand, have a greater bonding strength than their crystalline counterparts. Thus, via the first crystalline material 3004 and the first amorphous material 4004, the present techniques leverage these beneficial qualities of both (crystalline and amorphous) materials.

According to an exemplary embodiment, the first crystalline material 3004 makes up a bulk of the first component of the bonding interface between the device wafer 2004 and a carrier wafer 5004 (see below). Doing so serves to maximize heat dissipation across the bonding interface. For instance, in the example shown, the first crystalline material 3004 has a thickness T1, and the first amorphous material 4004 has a thickness T2, where T1 is greater than (>) T2.

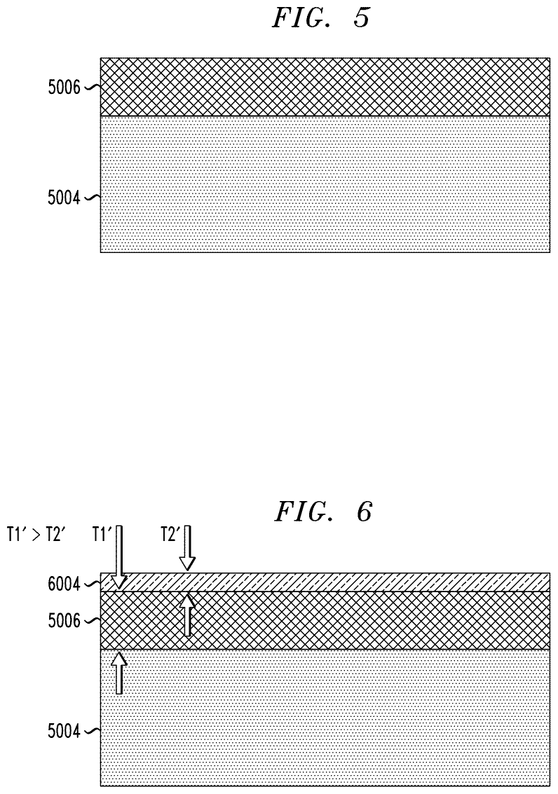

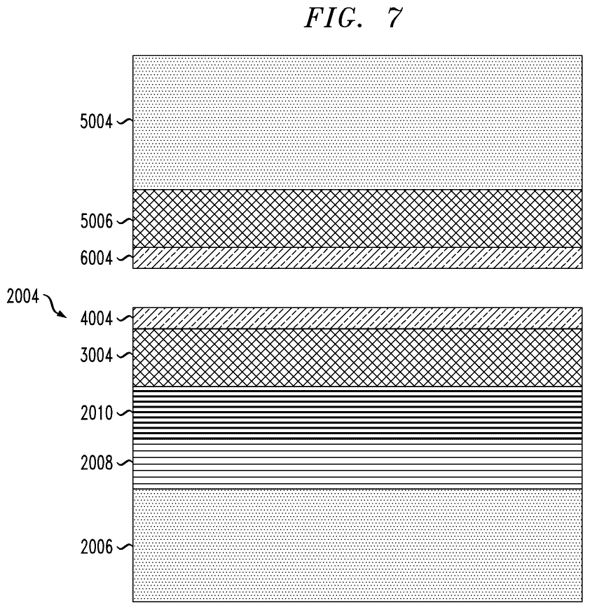

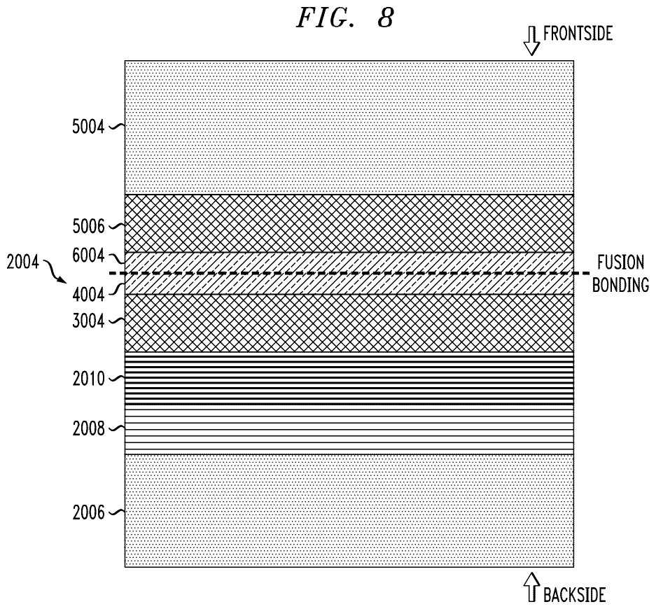

A similar process is then used to form the second component of the bonding interface on the carrier wafer 5004. In the same manner as above, this second component of the bonding interface also includes dual crystalline (FIG. 5) and amorphous (FIG. 6) materials. Namely, referring to FIG. 5, a second crystalline material 5006 is deposited onto the carrier wafer 5004. Suitable carrier wafers include, but are not limited to, silicon, silicon carbide and/or glass wafers. As will be described in detail below, the use of the carrier wafer 5004 will enable the assembly to be flipped, thereby permitting backside processing for the backside power distribution network 10004.

Referring to FIG. 6, a second amorphous material 6004 is deposited on the second crystalline material 5006. The second crystalline material 5006 and the second amorphous material 6004 together form the second component of the bonding interface on the carrier wafer 5004. Via the second crystalline material 5006 and the second amorphous material 6004, the present techniques leverage the beneficial thermal conductivity and bonding strength qualities of both (crystalline and amorphous) materials.

According to an exemplary embodiment, the second crystalline material 5006 makes up a bulk of the second component of the bonding interface between the device wafer 2004 and the carrier wafer 5004. Doing so serves to maximize heat dissipation across the bonding interface. For instance, in the example shown, the second crystalline material 5006 has a thickness T1′, and the second amorphous material 6004 has a thickness T2′, where T1′>T2′.

Suitable materials for the first crystalline material 3004 and the second crystalline material 5006 include, but are not limited to, crystalline solids of dielectric materials such as AlN, TiO₂, SiO₂, diamond, BN and/or BeO, which can be deposited using techniques known to those of skill in the art. As provided above, crystalline materials can improve heat dissipation, but result in voids that decrease bonding strength. This is why amorphous materials are also employed at the bonding interface to increase bond strength.

Similarly, suitable materials for the first amorphous material 4004 and the second amorphous material 6004 include, but are not limited to, amorphous solids of dielectric materials such as AlN, TiO₂, SiO₂ and/or SiCN, which can be deposited using techniques known to those of skill in the art. As provided above, amorphous materials offer better coverage and adhesion to improve bonding strength.

According to an exemplary embodiment, any combination of the dielectric materials provided above can be employed. For instance, embodiments are contemplated herein where crystalline and amorphous counterparts of the same dielectric material are employed for the first crystalline material 3004 vis-à-vis the first amorphous material 4004, and/or for the second crystalline material 5006 vis-à-vis the second amorphous material 6004. By way of non-limiting example only, this includes scenarios where the first crystalline material 3004 is crystalline AlN (or crystalline TiO₂, SiO₂, diamond, BN, BeO, etc.) and the first amorphous material 4004 is amorphous AlN (or amorphous TiO₂, SiO₂, SiCN, etc.). In that scenario, the second crystalline material 5006 also may be crystalline AlN (or crystalline TiO₂, SiO₂, diamond, BN, BeO, etc.) and the second amorphous material 6004 may also be amorphous AlN (or amorphous TiO₂, SiO₂, SiCN, etc.).

Embodiments are also contemplated herein where crystalline and amorphous counterparts of different dielectric materials are employed for the first crystalline material 3004 vis-à-vis the first amorphous material 4004, and/or for the second crystalline material 5006 vis-à-vis the second amorphous material 6004. By way of non-limiting example only, this includes scenarios where the first crystalline material 3004 is a crystalline solid of one of the above dielectric materials, e.g., crystalline AlN (or crystalline TiO₂, SiO₂, diamond, BN, BeO, etc.), and the first amorphous material 4004 is an amorphous solid of another one of the above dielectric materials, e.g., amorphous TiO₂ (or amorphous AlN, SiO₂, SiCN, etc.). Similarly, with this scenario, the second crystalline material 5006 is a crystalline solid of one of the above dielectric materials, e.g., crystalline AlN (or crystalline TiO₂, SiO₂, diamond, BN, BeO, etc.), and the second amorphous material 6004 is an amorphous solid of another one of the above dielectric materials, e.g., amorphous TiO₂ (or amorphous AlN, SiO₂, SiCN, etc.).

Further, any combination of the above may be employed. By way of non-limiting example only, this includes scenarios where the first crystalline material 3004 is crystalline AlN (or crystalline TiO₂, SiO₂, diamond, BN, BeO, etc.) and the first amorphous material 4004 is amorphous AlN (or amorphous TiO₂, SiO₂, SiCN, etc.), and where the second crystalline material 5006 is a crystalline solid of one of the above dielectric materials, e.g., crystalline AlN (or crystalline TiO₂, SiO₂, diamond, BN, BeO, etc.), and the second amorphous material 6004 is an amorphous solid of another one of the above dielectric materials, e.g., amorphous TiO₂ (or amorphous AlN, SiO₂, SiCN, etc.), or vice versa.

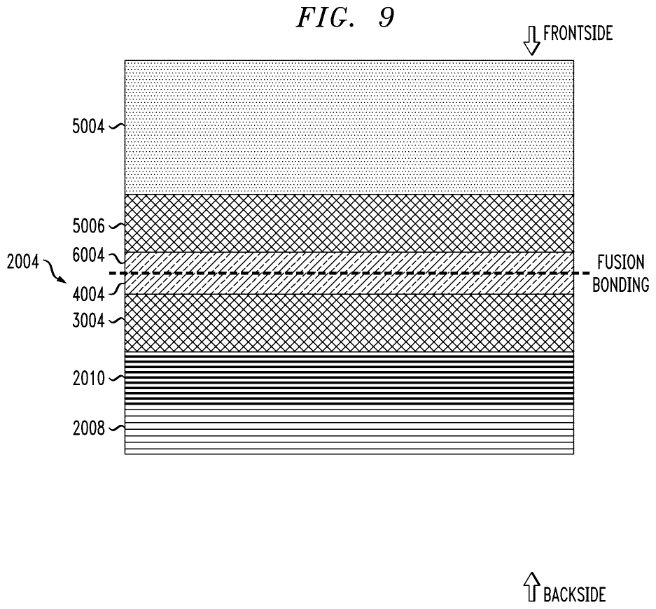

Referring to FIG. 7, the carrier wafer 5004 is flipped to enable face-to-face bonding with the device wafer 2004. Namely, as shown in FIG. 7, flipping the carrier wafer 5004 places the first amorphous material 4004 (of the device wafer 2004) directly opposite the second amorphous material 6004 (of the carrier wafer 5004).

Referring to FIG. 8, the device wafer 2004 and the carrier wafer 5004 are bonded to one another via fusion bonding between the first amorphous material 4004 (of the device wafer 2004) and the second amorphous material 6004 (of the carrier wafer 5004). By way of example only, this fusion bonding between the first amorphous material 4004 and the second amorphous material 6004 can involve thermal compression bonding, hybrid bonding, etc.

Attachment to the carrier wafer 5004 enables further processing of the device wafer 2004 to be performed. For instance, by way of example only, processing can be employed on the device wafer 2004 to form additional backside structures on the device wafer 2004 such as the backside power distribution network 10004. To do so, the assembly (i.e., the device wafer 2004 and the carrier wafer 5004) is flipped, meaning that what was once at the bottom of device wafer 2004 and the carrier wafer 5004 is now on the top, and vice versa. For instance, the substrate 2006 (of the device wafer 2004) would now be on top, and the carrier wafer 5004 would be on the bottom. Doing so enables top-down processing to be performed on the backside of the device wafer 2004. However, for consistency, the figures themselves have not been flipped in the drawings with the express understanding that processes now being performed on the backside of the device wafer 2004 (see label) would in practice be performed from the top-down on a flipped wafer.

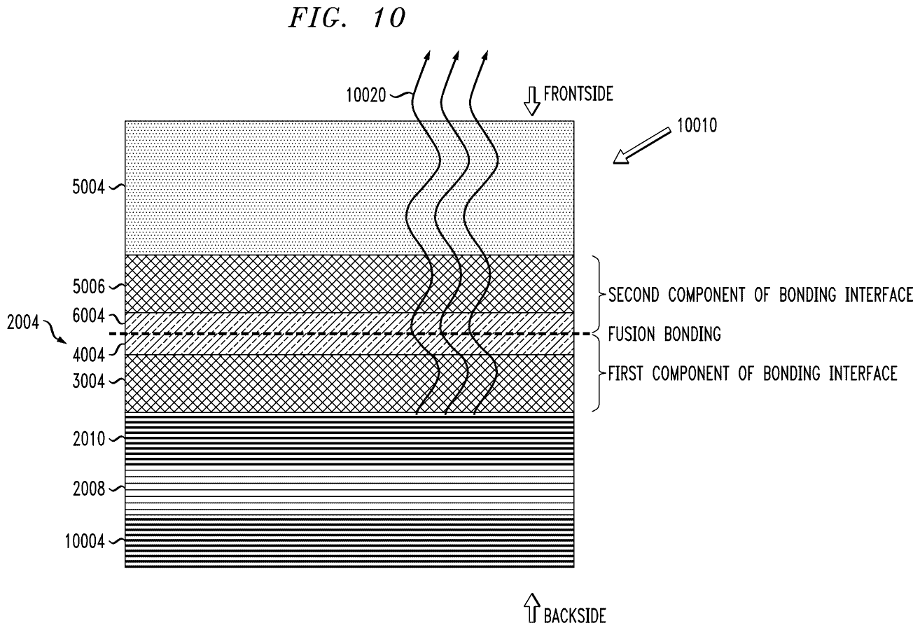

Referring to FIG. 9, an etch is next performed to remove the substrate 2006. As provided above, the substrate 2006 can be formed from Si. In that case, an Si-selective etch can be used to remove the substrate 2006.

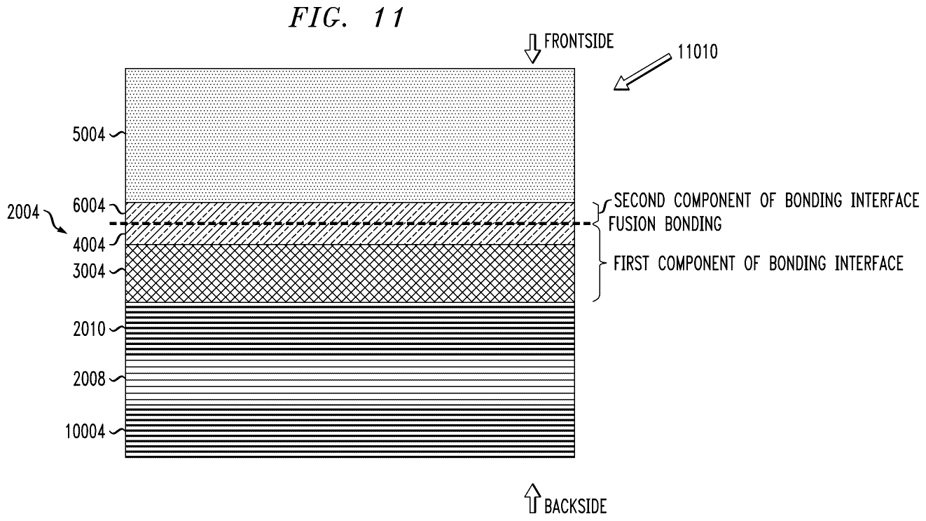

Referring to FIG. 10, the backside power distribution network 10004 is formed on the device layer 2008 on the backside of the device wafer 2004. The backside power distribution network 10004 generally includes backside interconnect structures such as conductive vias and metal lines commonly formed to interconnect various devices, with the metal lines making lateral connections and the vias making vertical connections amongst different metallization levels. Standard metallization techniques can be employed to form the backside power distribution network 10004. While the individual interconnects present in the backside power distribution network 10004 are not specifically shown in the figures, given the teachings herein, one skilled in the art would understand how such a backside power distribution network 10004 is implemented for a given semiconductor device application.

Now present is a semiconductor device 10010 having the backside power distribution network 10004 and a bonding interface between the device wafer 2004 and the carrier wafer 5004, where the (dual crystalline and amorphous) first component of the bonding interface includes the first crystalline material 3004 and the first amorphous material 4004 (of the device wafer 2004), and the (dual crystalline and amorphous) second component of the bonding interface includes the second crystalline material 5006 and the second amorphous material 6004 (of the carrier wafer 5004). As described above, the present techniques maximize both thermal conductivity and bonding strength through the use of crystalline materials (i.e., first crystalline material 3004 and the second crystalline material 5006) and amorphous materials (i.e., the first amorphous material 4004 and the second amorphous material 6004), respectively, at the bonding interface.

As further highlighted above, the backside power distribution network 10004 with its increased power density acts as a significant heat source in the present design. In that regard, the enhanced heat dissipation provided by the present dual crystalline and amorphous bonding interface advantageously compensates for the resulting increase in heat density from this heat source. Namely, as indicated by arrows 10020, heat generated at the device wafer 2004, including that from the backside power distribution network 10004, is effectively removed due to the enhanced heat dissipation of the dual crystalline and amorphous bonding interface.

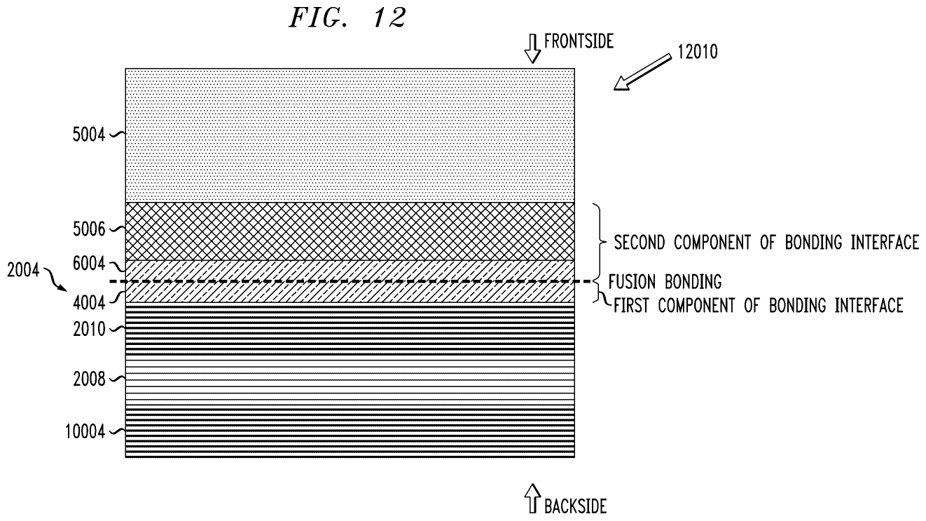

As variants to any of the above-described embodiments, the use of a crystalline material on only one side of the bonding interface, i.e., as part of the first component of the bonding interface formed on the device wafer OR as part of the second component of the bonding interface formed on the carrier wafer, is also contemplated herein which will still provide the present benefit of enhanced thermal conductivity while bonding strength is maintained via the counterpart amorphous materials. See, for example, semiconductor device 11010 of FIG. 11 and semiconductor device 12010 of FIG. 12. It is notable that like structures are numbered alike throughout the instant description and figures.

For instance, referring to FIG. 11, as with the previous examples the first component of the bonding interface between the device wafer 2004 and the carrier wafer 5004 includes the (dual crystalline and amorphous) first (and here only) crystalline material 3004 and the first amorphous material 4004 (of the device wafer 2004). However, in this variant the second component of the bonding interface includes only the second amorphous material 6004 (of the carrier wafer 5004).

Similarly, referring to another variant in FIG. 12, the first component of the bonding interface between the device wafer 2004 and the carrier wafer 5004 includes only the first amorphous material 4004 (of the device wafer 2004). Whereas the second component of the bonding interface includes the (dual crystalline and amorphous) second (and here only) crystalline material 5006 and the second amorphous material 6004 (of the carrier wafer 5004).

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1(SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor device, comprising:
a first wafer; and
a second wafer attached to the first wafer, wherein the first wafer comprises a first component of an interface between the first wafer and the second wafer, and the second wafer comprises a second component of the interface between the first wafer and the second wafer, and wherein at least one of the first component and the second component of the interface between the first wafer and the second wafer comprises dual crystalline and amorphous materials.

2. The semiconductor device of claim 1, wherein the first component and the second component of the interface between the first wafer and the second wafer each comprises the dual crystalline and amorphous materials.

3. The semiconductor device of claim 1, wherein the first component of the interface between the first wafer and the second wafer comprises:
a first crystalline material disposed on the first wafer; and
a first amorphous material disposed on the first crystalline material.

4. The semiconductor device of claim 3, wherein the second component of the interface between the first wafer and the second wafer comprises:
a second amorphous material disposed on the first amorphous material; and
a second crystalline material disposed on the second amorphous material, wherein the second wafer is disposed on the second crystalline material.

5. A semiconductor device, comprising:
a first crystalline material disposed on a first wafer, wherein the first wafer comprises a heat source;
a first amorphous material disposed on the first crystalline material;
a second amorphous material disposed on the first amorphous material;
a second crystalline material disposed on the second amorphous material; and
a second wafer disposed on the second crystalline material.

6. The semiconductor device of claim 5, wherein the first wafer comprises a device wafer, and the second wafer comprises a carrier wafer.

7. The semiconductor device of claim 6, wherein the heat source comprises a backside power distribution network present on a backside of the device wafer.

8. The semiconductor device of claim 5, wherein the first crystalline material has a thickness T1 and the first amorphous material has a thickness T2, and wherein T1>T2.

9. The semiconductor device of claim 5, wherein the second crystalline material has a thickness T1′ and the second amorphous material has a thickness T2′, and wherein T1′>T2′.

10. The semiconductor device of claim 5, wherein the first crystalline material and the second crystalline material each comprises a crystalline solid of a dielectric material selected from the group consisting of: AlN, TiO₂, SiO₂, diamond, BN, BeO, and combinations thereof.

11. The semiconductor device of claim 5, wherein the first amorphous material and the second amorphous material each comprises an amorphous solid of a dielectric material selected from the group consisting of: AlN, TiO₂, SiO₂, SiCN, and combinations thereof.

12. The semiconductor device of claim 5, wherein the first crystalline material comprises a crystalline solid and the first amorphous material comprises an amorphous solid of a same dielectric material.

13. The semiconductor device of claim 5, wherein the first crystalline material comprises a crystalline solid and the first amorphous material comprises an amorphous solid of different dielectric materials.

14. The semiconductor device of claim 5, wherein the second crystalline material comprises a crystalline solid and the second amorphous material comprises an amorphous solid of a same dielectric material.

15. The semiconductor device of claim 5, wherein the second crystalline material comprises a crystalline solid and the second amorphous material comprises an amorphous solid of different dielectric materials.

16. A method of forming a semiconductor device, the method comprising:
depositing a first crystalline material on a first wafer;
depositing a first amorphous material on the first crystalline material;
depositing a second crystalline material on a second wafer;
depositing a second amorphous material on the second crystalline material; and
bonding the first wafer and the second wafer to one another via fusion bonding between the first amorphous material and the second amorphous material.

17. The method of claim 16, wherein the first wafer comprises a device wafer, and the second wafer comprises a carrier wafer.

18. The method of claim 17, wherein the device wafer comprises: a substrate, a device layer disposed on the substrate, and a frontside interconnect layer disposed on the device layer, and wherein the first crystalline material is deposited onto the frontside interconnect layer.

19. The method of claim 17, further comprising:
forming a backside power distribution network on a backside of the device wafer.

20. The method of claim 16, wherein the fusion bonding comprises thermal compression bonding or hybrid bonding.
